(19) United States
(12) Patent Application Publication
(10) Pub. No.: US 2026/0235786 A1
(43) Pub. Date: Aug. 13, 2026

(54) IMAGING DEVICES FOR FIELD OF VIEW SPLITTING

(71) Applicant: NIL Technology ApS, Kongens Lyngby (DK)

(72) Inventor: Niklas Hansson, Askim (SE)

(21) Appl. No.: 19/474,944

(22) PCT Filed: Apr. 19, 2024
(86) PCT No.: PCT/EP2024/060841

§ 371 Date: Oct. 13, 2025

Related U.S. Application Data
(60) Provisional application No. 63/497,031, filed on Apr. 19, 2023.

(51) Int. Cl. G02B 1/00; G02B 5/04; H10F 39/00

(52) U.S. Cl. CPC G02B 1/002; G02B 5/045; H10F 39/806; G02B 2207/101

(57) ABSTRACT

An imaging device includes: an image sensor; a plurality of metastructures, each metastructure being arranged to focus light onto a different respective light sensitive region of the image sensor to capture a respective image with a respective field-of-view; and at least one optical element or additional metastructure configured to tilt a respective field of view of at least one of the plurality of metastructures to obtain a modified field-of-view.

### BACKGROUND

Meta-optical elements (MOEs) are examples of optical elements that employ a flat optic technology. An MOE has a metasurface that includes distributed small subwavelength structures (e.g., nanostructures or other meta-atoms) arranged to interact with light in a particular manner. The meta-atoms can, individually and/or collectively, interact with light waves to change a local amplitude, a local phase, or both, of an incoming light wave. MOEs can be used, for example, in optical applications to take advantage of the internal properties given by a tailored phase function, compared to classic, curved refractive lenses.

### SUMMARY

This specification describes technologies relating to imaging devices and in particular to imaging devices that can split the field of view into different regions.

In general, one or more aspects of the subject matter described in this specification can be embodied in one or more imaging devices that include: an image sensor; a plurality of metastructures, each metastructure being arranged to focus light onto a different respective light sensitive region of the image sensor to capture a respective image with a respective field-of-view; and at least one optical element or additional metastructure configured to tilt a respective field of view of at least one of the plurality of metastructures to obtain a modified field-of-view.

Implementations of the one or more imaging devices may have various features. For example, in some implementations, the at least one optical element or additional metastructure is a prism. The prism may be a wedge prism. The imaging device may include an aperture layer, in which the aperture layer includes at least one aperture, and wherein the prism is positioned in front of a first aperture of the aperture layer.

In some implementations, the at least one optical element or additional metastructure is a first additional metastructure. The imaging device may include an aperture layer, wherein the aperture layer comprises at least one aperture, and wherein the first additional metastructure is positioned in front of a first aperture of the aperture layer. The imaging device may include an aperture layer, wherein the aperture layer comprises at least one aperture, and wherein the first additional metastructure is positioned behind a first aperture of the aperture layer.

In some implementations, the imaging device includes an aperture layer, wherein the aperture layer comprises at least one aperture, and wherein each light sensitive region is aligned with a respective aperture of the aperture layer. The imaging device may include a filter layer, wherein the filter layer is arranged in front of or behind the aperture layer, and the filter layer may be configured to prevent incident light passing through a first aperture aligned with a first light sensitive region of the image sensor from being incident on a second light sensitive region of the image sensor.

In some implementations, the plurality of metastructures are aligned with respective light sensitive regions of the image sensor along a first plane that is parallel to a surface of the image sensor along which the light sensitive regions are provided. The imaging device may include an aperture layer, wherein the aperture layer comprises a plurality of aperture layers, and wherein each aperture is aligned with a respective metastructure of the plurality of metastructures. The imaging device may include at least two metastructures aligned with a first aperture of the aperture layer. Each metastructure of the at least two metastructures may be aligned with a first aperture is configured to perform a different optical function. The imaging device may include an additional optical element aligned with the first aperture. The additional optical element aligned with the first aperture may be a lens. The additional optical element aligned with the first aperture may be positioned in front of the at least two metastructures aligned with the first aperture. The additional optical element aligned with the first aperture may be positioned behind the at least two metastructures aligned with the first aperture. The at least one optical element or additional metastructure may be a prism. The imaging device may include an additional optical element aligned with the first aperture.

In some implementations, the filter layer may include a plurality of filters, wherein each filter of the plurality of filters is aligned with a respective aperture of the aperture layer.

Particular embodiments of the subject matter described in this specification can be implemented to realize one or more of the following advantages. The systems and techniques described herein can be used to image two or more areas of interest without having to image the regions between the areas of interest. In some implementations, this allows fabrication of a smaller and/or lower cost imaging system (e.g., a camera) compared to traditional imaging systems, while still obtaining the same information from the regions of interest.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of an imaging device with metastructures and optical elements for field-of-view splitting.

FIG. 2 shows an example of an imaging device with metastructures and optical elements for field-of-view splitting.

FIG. 3 is an example of an imaging device with metastructures and optical elements for field-of-view splitting.

Like reference numbers and designations in the various drawings indicate like elements.

### DETAILED DESCRIPTION

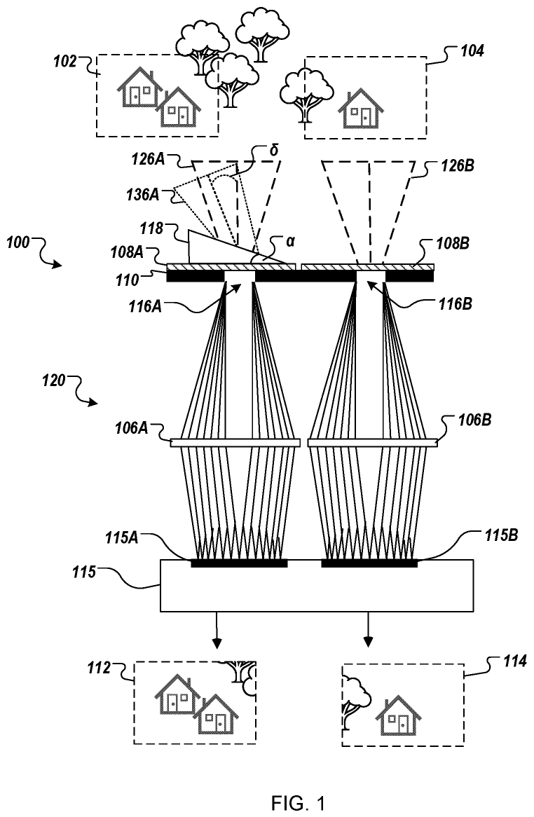

As shown in the example of FIG. 1, an imaging device 100 is operable to capture images 112, 114 of one or more areas of interest 102, 104 in a scene. Imaging device 100 is operable to capture images of one or more areas of interest without having to image regions in between the areas of interest. Imaging device 100 can be an array camera including a plurality of metastructures (e.g., metalenses) 106A, 106B, aligned with corresponding apertures 116A, 116B that can focus light reflected by objects in the scene toward respective light sensitive regions of an imaging sensor 115.

Each metastructure 106A, 106B has a metasurface, which refers to a surface with distributed small structures (e.g., meta-atoms) arranged to interact with light in a particular manner. For example, a metasurface can be a surface with a distributed array of nanostructures. The nanostructures are configured to interact, individually or collectively, with light waves so as to change a local amplitude, a local phase, or both, of an incoming light wave.

When meta-atoms (e.g., nanostructures) of a metasurface are in a particular arrangement, the metasurface may act as an optical element such as a lens, lens array, beam splitter, diffuser, polarizer, bandpass filter, or other optical element. In some instances, metasurfaces may perform optical functions that are traditionally performed by refractive and/or diffractive optical elements. The meta-atoms may be arranged, in some cases, in a pattern so that the metastructure functions, for example, as a lens, grating coupler or other optical element. In other instances, the meta-atoms need not be arranged in a pattern, and the metastructure can function, for example, as a fanout grating, diffuser or other optical element. In some implementations, the metasurfaces may perform other functions, including polarization control, negative refractive index transmission, beam deflection, vortex generation, polarization conversion, optical filtering, and plasmonic optical functions.

Metasurfaces may have carefully arranged “unit cells” or “meta-atoms” with sub-wavelength structures (e.g., nanostructures). The term “subwavelength” indicates that the nanostructures have at least one lateral dimension (parallel to the substrate on which they are disposed) that is less than a wavelength of light that is to be incident thereon. The meta-atoms can be composed, for example, of silicon. In general, the dimensions of the nanostructures scale with the shortest wavelength of interest. For example, in some implementations, the nanostructures can be in the form of nanoscale features having dimensions less than 1 micron. By adjusting the geometry of these unit cell elements, one can modify the phase above the elements in response to a plane wave. With the knowledge of the phase in terms of the geometry parameters, it is possible to create a metalens with an arbitrary phase profile by placing the meta-atoms at the necessary positions. In general, the derivative of the phase profile determines the ray bending. Each substrate together with its respective metasurface forms a metalens.

Metastructures 106A, 106B can be supported by a glass or other substrate. The substrate may be composed, for example, of glass (e.g., borosilicate glass such as D 263® glass manufactured by Schott) and can be attached (e.g., bonded) to a metastructure (e.g., metastructures 106A, 106B) using an adhesive such as a polymer glue, that is optically clear at the operating wavelength (e.g., infrared or visible). In some implementations, the adhesive is index matched to the substrate. In some cases, the metastructure includes multiple metasurfaces that are stacked on one another. For example, in some implementations, a metastructure can include a substrate-metasurface-adhesive-metasurface-substrate stacking configuration or a substrate-metasurface-adhesive-substrate-metasurface stacking configuration. Incorporating a stack of metasurfaces into a metastructure arrangement can, in some instances, facilitate a wide range of optical functionalities by having a resonant interaction between the stacked metasurfaces. Such optical functionalities can include, for example, near-field interactions, filtering functions, and/or plasmonics.

The imaging device 100 can include an aperture layer 110 and one or more filter layers, e.g., layers 108A, 108B. The aperture layer 110 includes apertures, e.g., apertures 116A, 116B, formed within the aperture layer and through which incident light from objects being imaged passes. The aperture layer 110 can be formed from various materials including, e.g., metal, polymer, or other material.

The light sensitive regions of the imaging sensor 115 may be arranged in a plane at or near the surface of the sensor 115, and may be aligned with corresponding apertures of the aperture layer 110. For instance, a first light sensitive region 115A may be aligned with a first aperture 116A. A second light sensitive region 115B may be aligned with a second aperture 116B. Though only two light sensitive regions and only two apertures are shown, additional light sensitive regions and apertures may be included in imaging device.

The one or more filter layers 108A, 108B serve to filter light having angles of incidence above or below a threshold angle of incidence with respect to a reference plane (depending on how the reference plane is chosen (e.g., as a normal to a metastructure or as parallel to a surface of the aperture layer)) in order to prevent incident light rays from passing through the apertures and impinging on adjacent light sensitive regions. For instance, the filter layer 108A may be configured to prevent light having angles that would otherwise impinge on light sensitive region 115B from passing through aperture 116A. Similarly, filter layer 108B may be configured to prevent light having angles that would otherwise impinge on light sensitive region 115A from passing through aperture 116B. The filter layers 108A, 108B may accomplish the filtering through absorption and/or reflection of light. Although shown as separate layers, the filter layers 108 may be provided as a single layer. Although shown as positioned above the aperture layer 110, the filter layers may be positioned below the aperture layer 110, i.e., closer to the light sensitive regions than the aperture layer 110. Although the present disclosure depicts a filter layer in the imaging devices 100, 200, a filter layer is not necessary.

Although the example of FIG. 1 shows the metastructures 106A, 106B spaced apart from the aperture layer 110 and the filter layers 108A, 108B,, in some cases the metastructures 106A, 106B can be disposed on the lower surface of the aperture layer 110 or on the lower surfaces of the filter layers 108A, 108B.

A configuration having a single metastructure is simple and makes it easier to control cross talk between the sub-modules. However, by providing two or more metastructures in the optical path between the object and sensor, it may be possible to more effectively counteract optical aberrations and reach better image quality. In some examples, each metastructure 106A, 106B can produce a respective image 112, 114 on a respective light sensitive region of the image sensor 115 or on different respective image sensors. Although only two metastructures 106A, 106B are shown in FIG. 1, the imaging device 100 can include a greater number of metastructures. In some instances, the metastructures 106A, 106B can be designed for a particular respective wavelength or range of wavelengths. That is, each metastructure may be designed to focus light, for example, in a visible region (e.g., red, blue, green) or infra-red region of the electromagnetic spectrum.

Each metastructure 106 and its corresponding aperture 116 may be understood to be a sub-module of the imaging device 100. The sub-modules comprised of the metalenses and their respective apertures have a respective field-of-view (FOV). For instance, the sub-module comprising metastructure 106A and aperture 116A has a FOV 126A. The sub-module comprising metastructure 106B and aperture 116B has FOV 126B. Although only two sub-modules are shown in FIG. 1, additional sub-modules may be included in the imagine device 100. The FOV is the part of a scene that is visible through the lens at a particular position and viewpoint in space. Objects outside the FOV when an image is captured are not recorded in the image. In order to image one or more regions in object space that are outside the FOV of the sub-modules, it is possible to use a single camera and increase the FOV to image all regions of interest. However, this would require a larger sensor and more advanced optics, which increases the cost and size of the system.

An alternative approach is to tilt the FOV of the individual sub-modules to target particular areas of interest of a scene (102, 104). Tilting the FOV in the sub-modules can, for example, be achieved by including an additional optical or metastructure element in the imaging device 100. The additional optical element can include, e.g., a prism such as a wedge prism. The optical element or metastructure element can be arranged in front of the sub-module, i.e., between the area of interest and the sub-module. For example, as shown in FIG. 1, an optical element such as a wedge prism 118 can be included to tilt the field of view 126A of a sub-module containing metastructure 106A and aperture 116A to obtain a new field of view 136A that includes area of interest 102 so that area of interest 102 can be captured in image 112.

A wedge prism is an optical element shaped such that incoming light is deflected by a fixed angle δ relative to a normal of the plane along which the filter layers 108A, 108B and/or aperture structure 110 is arranged. The fixed angle δ may be related to a characteristic angle α of the prism 118. The characteristic angle α may be defined as the angle between an input surface and an output surface of the prism 118. In the case of a wedge prism, the characteristic angle is the wedge angle. For instance, in the example shown in FIG. 1, the characteristic angle α is defined as the angle between the hypotenuse of the prism 118 and the surface of the prism 118 that faces the optical layer 108A. The field of view 126A of the corresponding sub-module can thus be tilted by this fixed angle δ to target certain areas of interest of a scene. The additional optical element for tilting the FOV, such as prism 118 can be fixed to the surface of the optical layer 108A (or to aperture layer 110) using, e.g., an optical adhesive. In some implementations, the additional optical element can be positioned to be spaced apart from the surface of the filter layers 108A, 108B and/or the aperture layer 110. For example, the imaging device 100 may include an air gap, vacuum, or other material with a refractive index of 1 positioned between the additional optical element and the filter layers 108A, 108B and/or the aperture layer 110.

Although the example of FIG. 1 shows a single prism 118, a plurality of prisms (e.g., a plurality of wedge prisms) can be included in the imaging device. In some examples, each prism can be associated with a respective metastructure of an imaging device. For instance, prism 118 is associated with metastructure 106A. An additional prism may be positioned over aperture 116B and thus associated with metastructure 106B. In some implementations in which the imaging device includes multiple prisms, where n is the total number of prisms and i refers the prism index, each prism i can have a respective characteristic angle αᵢ such that the FOV of a respective sub-module is tilted accordingly by a fixed angle δᵢ.

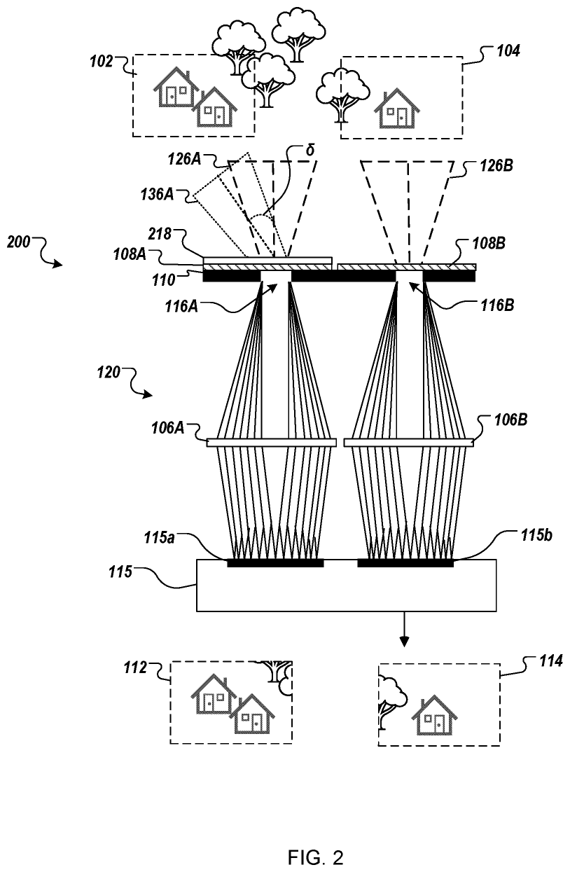

Optical elements, such as wedge prisms, can be heavy and can increase the weight and cost of imaging devices. As an alternative option, as explained above, in some implementations, tilting the FOV in the sub-modules can be achieved by instead including an additional metastructure element in the imaging device 100 to deflect light and thus the FOV by a fixed angle. The additional metastructure can be configured to exhibit a phase function that mimics a prism based. For example, FIG. 2 shows an imaging device 200 that is otherwise similar to imaging device 100 with the exception that it includes an additional metastructure element 218 in place of optical element 118. The additional metastructure element 218 is arranged in front of a filter layer, e.g., between filter layer 108A and the area of interest 102, instead of an additional optical element. The additional metastructure 218 can be configured to tilt the FOV 126A of metastructure 106A to obtain a new FOV 136A that achieves a viewpoint that includes area of interest 102 so that area of interest 102 can be captured by the imaging sensor 115 to produce image 112. Metastructure 218 acts similar to a prism, such as prism 118 in FIG. 1, by deflecting incoming rays by a fixed angle δ. Although shown positioned on the surface of filter layer 108A, in some implementations the additional metastructure 218 can be positioned between the filter layer 108A and the aperture layer 110.

The additional metastructure 218 can be positioned on the surface of the first filter layer 108 or aperture layer 110 using, e.g., an optical adhesive. In some implementations, the additional metastructure 218 is spaced apart from the surface of the filter layer 108A and/or aperture layer 110. For example, the imaging device 100 may include an air gap, vacuum, or other material with a refractive index of 1 positioned between the additional metastructure 218 and the filter layer 108A and/or aperture layer 110.

Referring again to FIG. 1, the prism 118 is preferably disposed above the corresponding aperture 116A of the sub-module over which the prism 118 is positioned. However in the case where the prism function is provided by metastructure 218, the metastructure can be disposed either above or below the apertures.

Although the implementations described so far depict the aperture layer 110 and thus the apertures of the aperture layer 110 positioned in front of the metastructures 106A, 106B, the apertures can be positioned below the metastructures 106A or in other locations, such as between metastructures. In some cases, the position of the aperture may be depend on the optical function of the imaging device.

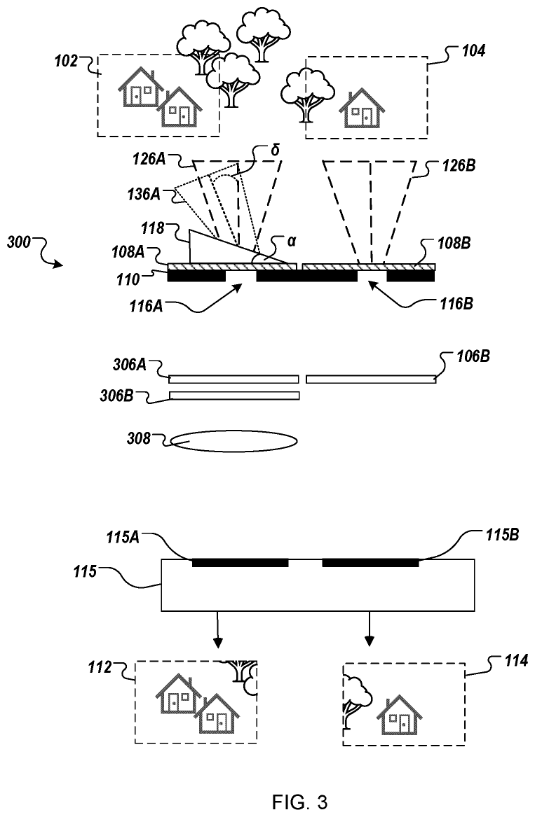

Moreover, one or more additional optical elements can be included in the imaging device. In some implementations, the imaging device may include an optical element for shifting the FOV, in addition to multiple metastructures and one or more additional optical elements. For instance, FIG. 3 is a schematic that illustrates an example configuration of an imaging device 300 that includes multiple metastructures and multiple optical elements. The imaging device 300 is similar to the imaging device of FIG. 1, with the exception that it includes multiple metastructures 306A, 306B aligned with aperture 116A, and includes one or more additional optical elements 308 aligned with aperture 116A. Each of metastructures may be configured to perform one or more optical functions including, but not limited to, polarization control, negative refractive index transmission, beam deflection, vortex generation, polarization conversion, optical filtering, and plasmonic optical functions. As an example, the first metastructure 306A may be configured to perform a first refraction of light, whereas the second metastructure 306B may be configured to perform a second refraction of light.

The one or more additional optical elements 308 may be configured for performing additional optical functions, such as, but not limited to, focusing, expanding, or collimating light. Although the optical element 308 is shown having a lens shape, it is not limited thereto. Although additional metastructures and optical elements are shown only aligned with aperture 116A, additional metastructures and optical elements may be aligned with other apertures of the imaging device 300. In some implementations, the optical element 118 shown in FIG. 3 for shifting the FOV is replaced by a metastructure, such as either metastructure 306A or 306B. The metastructure for shifting the FOV can be positioned in front of the aperture layer 110 and/or filter layer 108, or behind the aperture layer 110 and/or filter layer 108. For instance, the metastructure for shifting the FOV can be positioned between the aperture layer 110 and the first metastructure 306A or, if no 306A is included in the imaging device, then between the aperture layer 110 and the second metastructure 306B. Although the additional one or more optical elements 308 are shown in FIG. 3, the additional optical element(s) 308 are not necessary.

Although the present disclosure depicts the metastructure 108A being separate from the metastructure 218 (see FIG. 2), in some implementations, the functionality of the different metastructures may be combined into a single metastructure. The single metastructure may be positioned above or below the aperture layer 110. The single metastructure may be positioned above or below the filter layer 108. While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments.

Thus, particular embodiments of the invention have been described. Other embodiments are within the scope of the following claims. In addition, actions recited in the claims can be performed in a different order and still achieve desirable results.

1. An imaging device comprising:
an image sensor;
a plurality of metastructures, each metastructure being arranged to focus light onto a different respective light sensitive region of light sensitive regions of the image sensor to capture a respective image with a respective field-of-view; and
at least one optical element or additional metastructure configured to tilt a respective field of view of at least one of the plurality of metastructures to obtain a modified field-of-view.

2. The imaging device of claim 1 wherein the at least one optical element or additional metastructure is a prism.

3. The imaging device of claim 2, wherein the prism is a wedge prism.

4. The imaging device of claim 2, comprising an aperture layer, wherein the aperture layer comprises at least one aperture, and wherein the prism is positioned in front of a first aperture of the at least one aperture.

5. The imaging device of claim 1, wherein the at least one optical element or additional metastructure is a first additional metastructure.

6. The imaging device of claim 5, comprising an aperture layer, wherein the aperture layer comprises at least two apertures, and wherein the first additional metastructure is positioned in front of a first aperture of the at least two apertures.

7. The imaging device of claim 5, comprising an aperture layer, wherein the aperture layer comprises at least two apertures, and wherein the first additional metastructure is positioned behind a first aperture of the at least two apertures.

8. The imaging device of claim 1, comprising an aperture layer, wherein the aperture layer comprises at least two apertures, and wherein each light sensitive region of the light sensitive regions is aligned with a respective aperture of the at least two apertures.

9. The imaging device of claim 8, comprising a filter layer, wherein the filter layer is arranged in front of or behind the aperture layer, and wherein the filter layer is configured to block incident light passing through a first aperture aligned with a first light sensitive region of the light sensitive regions from being incident on a second light sensitive region of the light sensitive regions.

10. The imaging device of claim 1, wherein the plurality of metastructures are aligned with respective light sensitive regions of the light sensitive regions along a first plane that is parallel to a surface of the image sensor along which the light sensitive regions are provided.

11. The imaging device of claim 10, comprising an aperture layer, wherein the aperture layer comprises a plurality of apertures, and wherein each aperture of the plurality of apertures is aligned with a respective metastructure of the plurality of metastructures.

12. The imaging device of claim 11, comprising at least two metastructures aligned with a first aperture of the plurality of apertures.

13. The imaging device of claim 12, wherein each metastructure of the at least two metastructures aligned with the first aperture is configured to perform a different optical function.

14. The imaging device of claim 13, comprising an additional optical element aligned with the first aperture.

15. The imaging device of claim 14, wherein the additional optical element aligned with the first aperture is a lens.

16. The imaging device of claim 14, wherein the additional optical element aligned with the first aperture is positioned in front of the at least two metastructures aligned with the first aperture.

17. The imaging device of claim 14, wherein the additional optical element aligned with the first aperture is positioned behind the at least two metastructures aligned with the first aperture.

18. The imaging device of claim 13, wherein the at least one optical element or additional metastructure is a prism.

19. The imaging device of claim 18, comprising an additional optical element aligned with the first aperture.

20. The imaging device of claim 9, wherein the filter layer comprises a plurality of filters, wherein each filter of the plurality of filters is aligned with a respective aperture of the at least two apertures.
